(19) United States
(12) Patent Application Publication
(10) Pub. No.: US 2025/0287817 A1
(43) Pub. Date: Sep. 11, 2025

(54) DISPLAY PANEL

(71) Applicant: WUHAN CHINA STAR OPTOELECTRONICS SEMICONDUCTOR DISPLAY TECHNOLOGY CO., LTD., Wuhan, Hubei (CN)

(72) Inventor: Simin PENG, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 18/861,578

(22) PCT Filed: Jun. 29, 2023
(86) PCT No.: PCT/CN2023/103552

§ 371 Date: Oct. 30, 2024

(30) Foreign Application Priority Data
Aug. 10, 2022 (CN) 202210956012.6

(51) Int. Cl. H10K 59/80; H10K 59/122; H10K 59/131

(52) U.S. Cl. CPC H10K 59/8731; H10K 59/122; H10K 59/131

(57) ABSTRACT

A display panel is provided, including a substrate, a first inorganic layer, a first organic layer, and an encapsulation layer. The first organic layer includes a planarization layer disposed in a display area and a barrier structure disposed in a peripheral area. The display panel also includes a stacked structure consisting of an inorganic sub-layer, an organic sub-layer, and an inorganic sub-layer, sequentially layered. There is a gap between the organic sub-layer within the stacked structure and the barrier structure. The encapsulation layer contacts the first inorganic layer at the gap.

### FIELD OF DISCLOSURE

The present application relates to the field of display technology, and particularly to a display panel.

### DESCRIPTION OF RELATED ART

In the manufacturing process of organic light-emitting display (OLED) panels, to enhance production efficiency and reduce costs, individual OLED panels are typically fabricated on a display mother panel and then cut from it. During the preparation of the display mother panel, the overall thin encapsulation layer is generally an inorganic encapsulation layer prepared by chemical vapor deposition (CVD). Due to the inherent gap between the mask and the display mother panel, reactive gases can infiltrate areas masked by the mask, leading to the formation of shadows in these regions.

If a shadow falls on the cutting path, it results in an increased thickness of the inorganic film at the cutting location, which can induce edge cracks during the cutting process. These edge cracks have the potential to propagate from the encapsulation layer into the display area, causing panel edge failure. To ensure a high cutting yield, it is common practice to increase the distance between the edge of the CVD deposition area and the cutting path, thereby preventing shadows from overlapping with the cutting path. However, as the bezel width is continuously reduced, shadows inevitably encroach upon the cutting paths. The narrower the bezel, the thicker the shadow becomes, escalating the risk of cutting cracks and significantly impacting the lifespan of the display panel.

### SUMMARY OF INVENTION

One embodiment of the present application provides a display panel designed to address the problem of shadows covering cutting paths in conventional display panels, which leads to the formation of cutting cracks.

In order to address the above issues, the present application provides the following technical solutions.

The present application provides a display panel including a display area and at least one peripheral area located on at least one side of the display area, the display panel including:
a substrate;
a first inorganic layer disposed on one side of the substrate;
a first organic layer disposed on one side of the first inorganic layer away from the substrate, wherein the first organic layer includes a planarization layer disposed in the display area and a barrier structure disposed in the peripheral area; and
an encapsulation layer disposed on one side of the first organic layer away from the substrate;
wherein the display panel further includes a stacked structure disposed in the peripheral area and located on one side of the barrier structure away from the display area, the stacked structure including an inorganic sub-layer, an organic sub-layer, and an inorganic sub-layer, sequentially layered, wherein a gap is defined between the organic sub-layer and the barrier structure, and the encapsulation layer contacts the first inorganic layer at the gap.

In the display panel of the present application, the encapsulation layer includes a first inorganic encapsulation layer, a first organic encapsulation layer, and a second inorganic encapsulation layer, sequentially layered;
wherein the first inorganic encapsulation layer covers the display area and extends to cover the barrier structure, and the first inorganic encapsulation layer contacts the first inorganic layer at the gap.

In the display panel of the present application, the first organic layer further includes a first organic filler layer disposed on one side of the barrier structure away from the display area;
wherein the stacked structure includes the first inorganic layer, the first organic filler layer, and the first inorganic encapsulation layer, sequentially layered.

In the display panel of the present application, the first inorganic layer includes at least one groove defined on one side of the barrier structure away from the display area;
wherein the first organic filler layer covers the groove.

In the display panel of the present application, the first organic layer further includes:
a pixel definition layer disposed on one side of the planarization layer away from the substrate; and
a plurality of support pillars disposed on one side of the pixel definition layer away from the substrate;

wherein the first organic filler layer includes a same organic material as one or a combination of the planarization layer, the pixel definition layer, and the support pillars.

In the display panel of the present application, the stacked structure includes the first inorganic layer, the first organic filler layer, the first inorganic encapsulation layer, a second organic filler layer, and the second inorganic encapsulation layer, sequentially layered;
wherein the second organic filler layer includes a same organic material as the organic encapsulation layer.

In the display panel of the present application, the display panel further includes:
a second inorganic layer disposed on one side of the encapsulation layer away from the substrate; and
a third organic filler layer, disposed between the second inorganic layer and the encapsulation layer and located on one side of the barrier structure away from the display area;
wherein the stacked structure includes the first inorganic layer, the first organic filler layer, the first inorganic encapsulation layer, the second organic filler layer, the second inorganic encapsulation layer, the third organic filler layer, and the second inorganic layer, sequentially layered, and wherein the third organic filler layer includes a same organic material as the organic encapsulation layer.

In the display panel of the present application, the stacked structure includes the first inorganic encapsulation layer, a second organic filler layer, and the second inorganic encapsulation layer, sequentially layered;
wherein the second organic filler layer includes a same organic material as the organic encapsulation layer.

In the display panel of the present application, the first inorganic layer further includes at least one groove defined on one side of the barrier structure away from the display area, and the first organic layer further includes a crack prevention layer disposed between the barrier structure and the stacked structure, the crack prevention layer covering the groove.

In the display panel of the present application, a thickness of the organic sub-layer is in a range of 2 micrometers to 10 micrometers.

The present application provides a display panel including a display area and at least one peripheral area located on at least one side of the display area, characterized in that the display panel includes:
a substrate;
a first inorganic layer disposed on one side of the substrate;
a first organic layer disposed on one side of the first inorganic layer away from the substrate, wherein the first organic layer includes a planarization layer disposed in the display area and a barrier structure disposed in the peripheral area;
an encapsulation layer disposed on one side of the first organic layer away from the substrate; and
a driving circuit layer, disposed on one side of the substrate, including a plurality of inorganic film layers and a plurality of organic film layers, wherein the first inorganic layer includes one or more inorganic film layers combined within the driving circuit layer, and the first organic layer includes one or more organic film layers combined within the driving circuit layer;
wherein the display panel further includes a stacked structure disposed in the peripheral area and located on one side of the barrier structure away from the display area, the stacked structure including an inorganic sub-layer, an organic sub-layer, and an inorganic sub-layer, sequentially layered, wherein a gap is defined between the organic sub-layer and the barrier structure, and the encapsulation layer contacts the first inorganic layer at the gap.

In the display panel of the present application, the encapsulation layer includes a first inorganic encapsulation layer, a first organic encapsulation layer, and a second inorganic encapsulation layer, sequentially layered;
wherein the first inorganic encapsulation layer covers the display area and extends to cover the barrier structure, and the first inorganic encapsulation layer contacts the first inorganic layer at the gap.

In the display panel of the present application, the first organic layer further includes a first organic filler layer disposed on one side of the barrier structure away from the display area;
wherein the stacked structure includes the first inorganic layer, the first organic filler layer, and the first inorganic encapsulation layer, sequentially layered.

In the display panel of the present application, the first inorganic layer includes at least one groove defined on one side of the barrier structure away from the display area;
wherein the first organic filler layer covers the groove.

In the display panel of the present application, the first organic layer further includes:
a pixel definition layer disposed on one side of the planarization layer away from the substrate; and
a plurality of support pillars disposed on one side of the pixel definition layer away from the substrate;
wherein the first organic filler layer includes a same organic material as one or a combination of the planarization layer, the pixel definition layer, and the support pillars.

In the display panel of the present application, the stacked structure includes the first inorganic layer, the first organic filler layer, the first inorganic encapsulation layer, a second organic filler layer, and the second inorganic encapsulation layer, sequentially layered;
wherein the second organic filler layer includes a same organic material as the organic encapsulation layer.

In the display panel of the present application, the display panel further includes:
a second inorganic layer disposed on one side of the encapsulation layer away from the substrate; and
a third organic filler layer, disposed between the second inorganic layer and the encapsulation layer and located on one side of the barrier structure away from the display area;
wherein the stacked structure includes the first inorganic layer, the first organic filler layer, the first inorganic encapsulation layer, the second organic filler layer, the second inorganic encapsulation layer, the third organic filler layer, and the second inorganic layer, sequentially layered, and wherein the third organic filler layer includes a same organic material as the organic encapsulation layer.

In the display panel of the present application, the stacked structure includes the first inorganic encapsulation layer, the second organic filler layer, and the second inorganic encapsulation layer, sequentially layered;
wherein the second organic filler layer includes a same organic material as the organic encapsulation layer.

In the display panel of the present application, the first inorganic layer further includes at least one groove defined on one side of the barrier structure away from the display area, and the first organic layer further includes a crack prevention layer disposed between the barrier structure and the stacked structure, the crack prevention layer covering the groove.

In the display panel of the present application, wherein a thickness of the organic sub-layer is in a range of 2 micrometers to 10 micrometers.

### BENEFICIAL EFFECTS

The beneficial effects of this application are as follows: The display panel provided in this embodiment includes a first inorganic layer, a first organic layer, and an encapsulation layer. The first organic layer includes a planarization layer in the display area and a barrier structure in the peripheral area. A stacked structure is formed in the peripheral area, located on one side of the barrier structure away from the display area. The stacked structure includes an inorganic sub-layer, an organic sub-layer, and an inorganic sub-layer, sequentially layered. A gap is formed between the organic sub-layer and the barrier structure, allowing the encapsulation layer to contact the first inorganic layer at the gap, thereby forming a complete encapsulation. Within the stacked structure, the organic sub-layer is positioned between two adjacent inorganic sub-layers, creating an inorganic/organic/inorganic alternately-layered structure. This is analogous to dividing a thick inorganic film layer into multiple thinner inorganic sub-layers. This configuration significantly reduces the risk of cracks forming in the stacked structure during the cutting of the display mother panel. This approach enables the realization of ultra-narrow bezels while simultaneously enhancing the performance and longevity of the light-emitting devices in the display panel.

### BRIEF DESCRIPTION OF DRAWINGS

To clarify the technical solutions in the embodiments of the present application more clearly, a brief introduction to the drawings used in the description of the embodiments is provided below. It is apparent that the drawings described below are only some embodiments of this application. Other drawings can also be derived by those skilled in the art without creative effort based on these drawings.

FIG. 1A is a schematic top view of a display panel provided in an embodiment of the present application.

FIG. 1B is a schematic top view of a display mother panel provided in an embodiment of the present application.

FIG. 2A is a first type schematic cross-sectional view taken along line A-A of FIG. 1B.

FIG. 2B is a first type schematic cross-sectional view of the display panel provided in an embodiment of the present application.

FIG. 3 is a schematic partial cross-sectional view at point B of FIG. 1B.

FIG. 4A is a second type schematic cross-sectional view taken along line A-A of FIG. 1B.

FIG. 4B is a second type schematic cross-sectional view of the display panel provided in an embodiment of the present application.

FIG. 5A is a third type schematic cross-sectional view taken along line A-A of FIG. 1B.

FIG. 5B is a third type schematic cross-sectional view of the display panel provided in an embodiment of the present application.

FIG. 6A is a fourth type schematic cross-sectional view taken along line A-A of FIG. 1B.

FIG. 6B is a fourth type schematic cross-sectional view of the display panel provided in an embodiment of the present application.

### DETAILED DESCRIPTION OF EMBODIMENTS

In conjunction with the drawings of the embodiments of the present application, the technical solutions in the embodiments of this application are described clearly and completely. Obviously, the embodiments described herein are only a part of the embodiments of this application and not all of them. Based on the embodiments of this application, all other embodiments obtained by those skilled in the art without creative effort fall within the scope of protection of this application. Furthermore, it should be understood that the specific embodiments described here are used only to illustrate and explain this application and are not intended to limit this application. In this application, unless otherwise specified, directional terms such as “up” and “down” usually refer to the orientation of the device in actual use or operation, specifically as indicated in the diagram directions of the drawings; and “inside” and “outside” refer to the contour of the device.

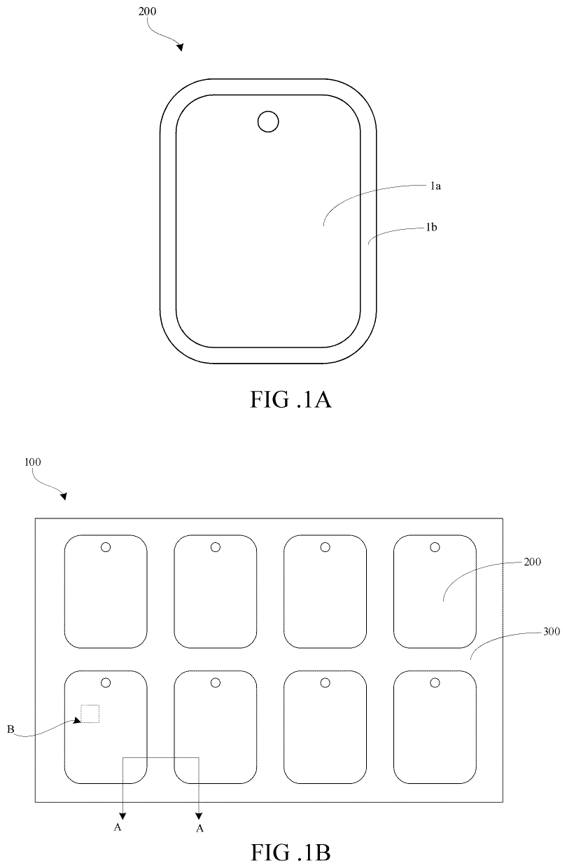

Please refer to FIGS. 1A and 1B, where FIG. 1A is a schematic top view of a display panel provided in one embodiment of the present application, and FIG. 1B is a schematic top view of a display mother panel provided in an embodiment of this application. This embodiment provides a display panel 200, which includes a display area 1a and a peripheral area 1b located on at least one side of the display area 1a.

The display panel 200 is cut from the display mother panel 100, as shown in FIG. 1B. The display mother panel 100 includes a substrate base 300 and a plurality of display panels 200 set on one side of the substrate base 300, with the display panels 200 being formed by cutting the display mother panel 100. Specifically, the display mother panel 100 includes a cutting zone 1c equipped with cutting paths. The display mother panel 100 is cut along these cutting paths to form multiple independent display panels 200. In this embodiment, the cutting techniques used may include wheel cutting, laser cutting, or a combination of both.

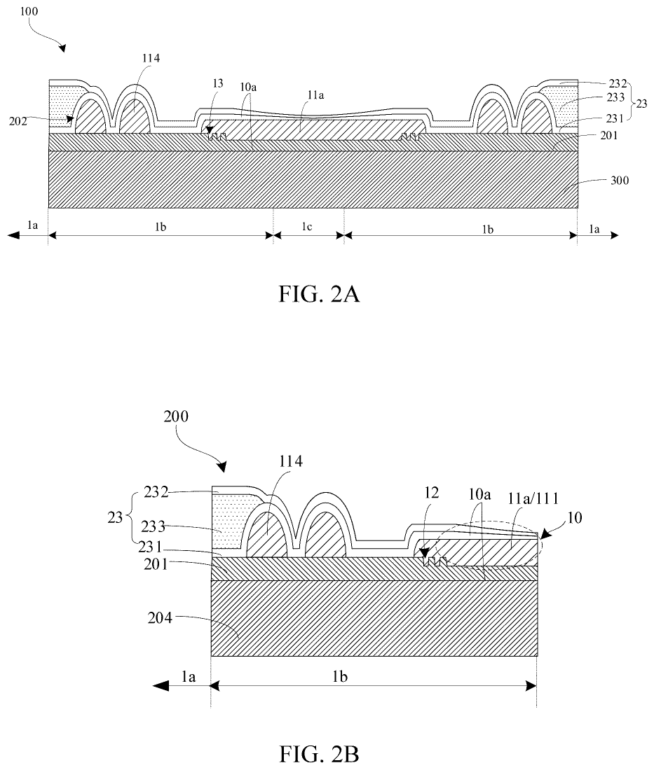

Please refer to FIGS. 2A and 2B. FIG. 2A is a first type schematic cross-sectional view taken along line A-A of FIG. 1B, and FIG. 2B is a first type schematic cross-sectional view of the display panel provided in one embodiment of the present application. FIG. 2A shows a cross-section of the display mother panel 100 before cutting, while FIG. 2B shows a cross-section of the display panel 200 after cutting.

The display panel 200 includes a substrate 204, a first inorganic layer 201, a first organic layer 202, and an encapsulation layer 23. The first inorganic layer 201 is positioned on one side of the substrate 204. The first organic layer 202 is set on one side of the first inorganic layer 201 that is away from the substrate 204 and includes a planarization layer set in the display area 1a and a barrier structure 114 set in the peripheral area 1b. The encapsulation layer 23 is positioned on one side of the first organic layer 202 that is away from the substrate 204.

The display panel 200 also includes a stacked structure 10 located in the peripheral area 1b and on one side of the barrier structure 114 that is away from the display area 1a. The stacked structure 10 consists of an inorganic sub-layer 10a, an organic sub-layer 11a, and an inorganic sub-layer 10a sequentially layered. There is a gap between the organic sub-layer 11a and the barrier structure 114, where the encapsulation layer 23 contacts the first inorganic layer 201 at the gap.

It is understandable that as bezels are progressively reduced, shadows increasingly encroach upon the cutting paths. The narrower the bezel, the thicker the shadow, resulting in a thicker inorganic stack in the cutting zone 1c. This, in turn, elevates the risk of cutting cracks. The present application addresses this challenge by introducing an organic sub-layer 11a into the stacked structure 10. This organic sub-layer 11a is positioned between adjacent inorganic sub-layers 10a, creating a multi-layered inorganic/organic/inorganic structure. Effectively, this divides the combined inorganic film layers into multiple thinner inorganic sub-layers 10a, significantly mitigating the risk of cracks during the cutting process of the display mother panel 100. This approach not only enables the realization of ultra-narrow bezels but also enhances the performance and longevity of the light-emitting devices within the display panel 200.

It should be noted that in FIG. 2B, the display area 1a and the peripheral area 1b are illustratively differentiated by dashed lines. The display area 1a accommodates light-emitting units and pixel circuits that drive these light-emitting units, while the peripheral area 1b serves as a bezel region of the display panel 200, housing the driving circuits and various signal lines.

The substrate 204 and the substrate base 300 can be the same film layer, with the substrate 204 being cut from the substrate base 300. In this embodiment, the substrate 204 can be a flexible substrate. The flexible substrate may be composed of a single or multiple layers of flexible organic films, which can resist stress impacts to some extent, helping to reduce the risk of cracks in the stacked structure 10 on the substrate 204 during the cutting process.

Optionally, the flexible substrate can be made from materials such as polyimide (PI), polyethylene terephthalate (PET), polybutylene naphthalate (PBN), or polycarbonate. In this embodiment, the flexible substrate uses a single layer of PI film. In other embodiments of the present application, the flexible substrate can be a multi-layer PI film, a multi-layer PET film, or have a multi-layer structure with alternating layers of PI and PET films.

The encapsulation layer 23 serves to protect the light-emitting units and is implemented using a thin-film encapsulation method. This encapsulation layer 23 can employ a multi-layered inorganic/organic/inorganic structure. For example, in this embodiment, the encapsulation layer 23 includes a first inorganic encapsulation layer 231, a second inorganic encapsulation layer 232, and an organic encapsulation layer 233, sequentially stacked away from the substrate 204. Both the first and second inorganic encapsulation layers 231 and 232 extend from the display area 1a to cover the peripheral area 1b, while the organic encapsulation layer 233 covers the display area 1a.

The first inorganic encapsulation layer 231 and the second inorganic encapsulation layer 232 extend from the display area 1a to the peripheral area 1b and cover the barrier structure 114. The first inorganic encapsulation layer 231 contacts the first inorganic layer 201 at the gap, thus forming a complete encapsulation. This arrangement provides encapsulation protection for the wiring and other components in the peripheral area 1b, primarily acting to block the ingress of water and oxygen, thereby enhancing the effectiveness of the encapsulation.

Optionally, the first and second inorganic encapsulation layers 231 and 232 can be fabricated from materials such as nitrides, oxides, oxynitrides, nitrates, carbides, or any combination thereof.

The first organic encapsulation layer 233 typically terminates at the barrier structure 114, serving a role in auxiliary encapsulation and planarization. Optionally, the first organic encapsulation layer 233 can be made from materials such as acrylonitrile, hexamethyldisiloxane, polyacrylates, polycarbonates, polystyrene, or similar materials.

In this embodiment of the application, the first organic layer 202 further includes a first organic filler layer 111 positioned on one side of the barrier structure 114 away from the display area 1a. In this configuration, the stacked structure 10 includes the first inorganic layer 201, the first organic filler layer 111, and the first inorganic encapsulation layer 231, sequentially layered.

It is understood that in conventional technologies, the first inorganic layer 201 and the first inorganic encapsulation layer 231 in the peripheral area 1b are in direct contact, with the two inorganic layers stacked together. This is equivalent to having a single, thicker inorganic film layer, which increases the risk of cracking during the cutting process. This application addresses this by introducing the first organic filler layer 111 between the first inorganic layer 201 and the first inorganic encapsulation layer 231. This separates the first inorganic layer 201 and the first inorganic encapsulation layer 231, preventing direct contact. This is analogous to splitting the inorganic stack formed by the first inorganic layer 201 and the first inorganic encapsulation layer 231, resulting in an inorganic/organic/inorganic film structure. Essentially, this divides a thicker inorganic film layer into two thinner inorganic sub-layers 10a, thereby reducing the risk of cracks during cutting.

It should be noted that the first organic filler layer 111 is an organic film layer that serves as a stress buffer, further reducing the risk of cracking during the cutting process.

Moreover, the first inorganic layer 201 includes at least one groove 12, located on one side of the barrier structure 114 away from the display area 1a, which is covered by the first organic filler layer 111. This groove 12 acts to block cutting cracks from extending from the peripheral area 1b to the display area 1a, thus lowering the risk of failure in the light-emitting units located in the display area 1a.

It should also be mentioned that the thickness of each organic sub-layer 11a ranges from 2 micrometers to 10 micrometers. The reason for setting this thickness range is that on one hand, the organic sub-layer 11a needs to function as a buffer, thus its thickness should not be too thin; on the other hand, if the organic sub-layer 11a is too thick during the cutting of the display mother panel 100, it tends to be prone to adhesion. Preferably, the thickness of each organic sub-layer 11a ranges from 5 micrometers to 10 micrometers.

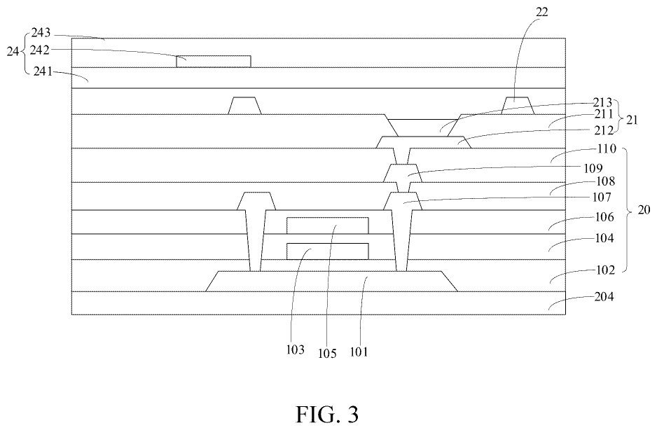

Specifically, please refer to FIG. 3, which is a schematic partial cross-sectional view at point B of FIG. 1B. The display panel 200 includes a driving circuit layer 20 and a light-emitting device layer 21. The driving circuit layer 20 is located on one side of the substrate 204, while the light-emitting device layer 21 is positioned on one side of the driving circuit layer 20 that is away from the substrate 204 and is located in the display area 1a. The encapsulation layer 23 covers one side of the light-emitting device layer 21 that is away from the substrate 204. The light-emitting device layer 21 includes multiple light-emitting units, and the driving circuit layer 20 includes multiple pixel driving circuits that are used to drive the light-emitting units. The pixel driving circuits include multiple thin-film transistors.

The driving circuit layer 20 includes inorganic film layers and organic film layers. Specifically, the driving circuit layer 20 can include multiple inorganic film layers and multiple organic film layers. In this embodiment of the application, the first inorganic layer 201 can be one of the inorganic film layers in the driving circuit layer 20, or it can be a combination of multiple inorganic film layers. Similarly, the first organic layer 202 can be one of the organic film layers in the driving circuit layer 20, or a combination of multiple organic film layers.

In this embodiment, the thin-film transistors can be of various structures, such as etch stop type, back channel etched type, or top gate type, with no specific limitations.

As shown in FIG. 3, in this embodiment of the application, the thin-film transistors are exemplified as top-gate thin-film transistors. The driving circuit layer 20 includes a semiconductor layer 101, a first gate insulating layer 102, a first gate layer 103, a second gate insulating layer 104, a second gate layer 105, an interlayer dielectric 106, a first source-drain metal layer 107, a first planarization layer 108, a second source-drain metal layer 109, and a second planarization layer 110.

The semiconductor layer 101 is located on one side of the substrate 204, the first gate insulating layer 102 covers one side of the semiconductor layer 101 that is away from the substrate 204, the first gate layer 103 is positioned on one side of the first gate insulating layer 102 that is away from the substrate 204, the second gate insulating layer 104 covers one side of the first gate layer 103 that is away from the substrate 204, the second gate layer 105 is disposed on one side of the second gate insulating layer 104 that is away from the substrate 204, the interlayer dielectric 106 covers one side of the second gate layer 105 that is away from the substrate 204, the first source-drain metal layer 107 is located on one side of the interlayer dielectric 106 that is away from the substrate 204, the first planarization layer 108 covers one side of the first source-drain metal layer 107 away from the substrate 204, the second source-drain metal layer 109 is positioned on one side of the first source-drain metal layer 107 that is away from the substrate 204, and the second planarization layer 110 covers one side of the second source-drain metal layer 109 away from the substrate 204.

In this embodiment, the first inorganic layer 201 can include one or more layers selected from the first gate insulating layer 102, the second gate insulating layer 104, and the interlayer dielectric 106. Similarly, the first organic layer 202 can include one or more layers combined from the first planarization layer 108 and the second planarization layer 110.

Specifically, the light-emitting device layer 21 includes a pixel definition layer 211. The pixel definition layer 211 is positioned on one side of the second planarization layer 110 that is away from the substrate 204, and the pixel definition layer 211 is an organic film. The light-emitting device layer 21 also includes an anode layer 212, a light-emitting functional layer 213, and a cathode layer (not shown in the drawing). The pixel definition layer 211 defines a plurality of pixel openings, and the light-emitting functional layer 213 is located within the pixel openings. The light-emitting functional layer 213 can also include an electron injection layer, an electron transport layer, a light-emitting layer, a hole transport layer, and a hole injection layer, all situated between the anode layer 212 and the cathode layer.

The display panel 200 also includes a plurality of support pillars 22. The support pillars are located on one side of the pixel definition layer 211 that is away from the substrate 204 and disposed in the display area 1a. The material of the support pillars 22 is an organic material.

In this embodiment, the first organic filler layer 111 can include the same material as any one or more layers among the planarization layer, the pixel definition layer 211, and the support pillars 22. That is, the first organic filler layer 111 can be manufactured using the same process as any one or more of the planarization layer, the pixel definition layer 211, and the support pillars 22, which is beneficial for reducing the number of manufacturing steps.

Specifically, the first organic filler layer 111 includes the same material used in any one or more of the following layers: the first planarization layer 108, the second planarization layer 110, the pixel definition layer 211, and the support pillars 22.

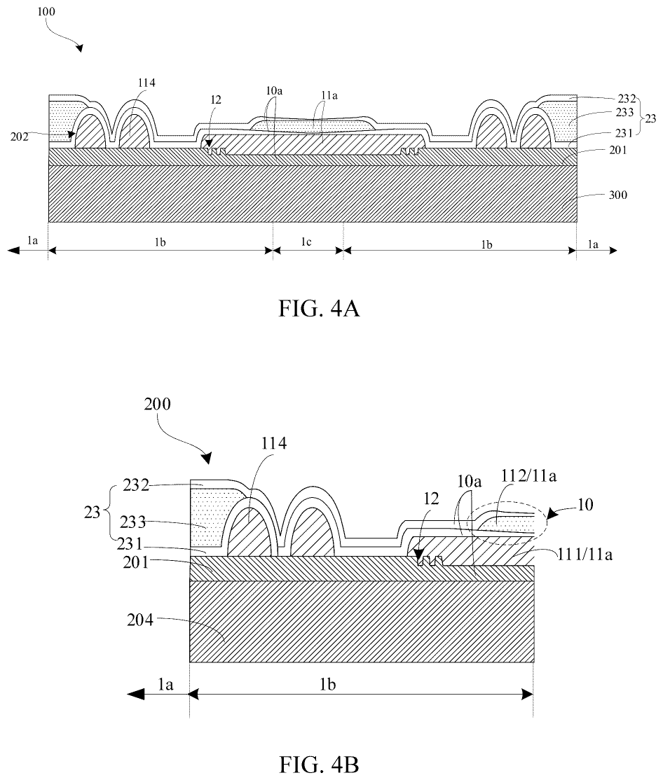

In one embodiment, please refer to FIGS. 4A and 4B. FIG. 4A is a second type schematic cross-sectional view taken along line A-A of FIG. 1B, and FIG. 4B is a second type schematic cross-sectional view of the display panel provided in one embodiment of the present application. The difference between FIGS. 4A and 4B compared to FIGS. 2A and 2B is that the stacked structure 10 also includes a second organic filler layer 112 positioned between the first inorganic encapsulation layer 231 and the second inorganic encapsulation layer 232.

In this case, the stacked structure 10 consists of sequentially layered components: the first inorganic layer 201, the first organic filler layer 111, the first inorganic encapsulation layer 231, the second organic filler layer 112, and the second inorganic encapsulation layer 232.

It is understandable that in the peripheral area 1b, if the first inorganic encapsulation layer 231 and the second inorganic encapsulation layer 232 were in direct contact, these two film layers would be equivalent to a single, thicker inorganic film layer. This would increase the risk of cracks forming during the cutting process. By introducing the second organic filler layer 112, this application ensures that the first inorganic encapsulation layer 231 and the second inorganic encapsulation layer 232 are spaced apart, preventing direct contact. This is analogous to splitting the thick inorganic film layer formed by the stacking of the first and second inorganic encapsulation layers 231 and 232. Consequently, the stacked structure 10 forms an inorganic/organic/inorganic/organic/inorganic layered structure, which reduces the risk of cracks during cutting.

Similarly, the second organic filler layer 112 is an organic film layer that acts as a stress buffer, further reducing the risk of cracks during the cutting process.

In this embodiment, the second organic filler layer 112 can consist of the same organic material as the organic encapsulation layer 233. Structurally, the second organic filler layer 112 can be set in the same layer as the organic encapsulation layer 233; from a manufacturing process perspective, the second organic filler layer 112 and the organic encapsulation layer 233 are formed using the same process, which is advantageous for reducing steps and lowering costs.

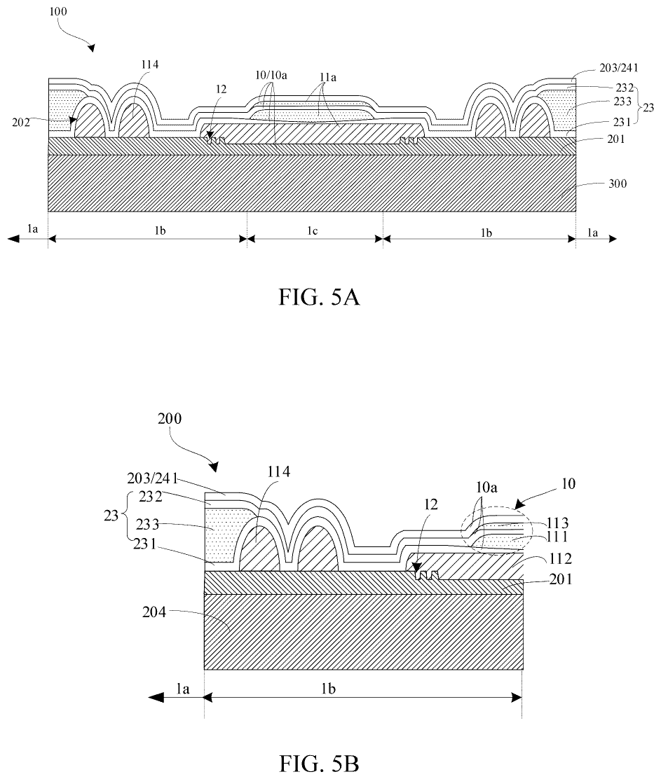

In one embodiment, please refer to FIGS. 5A and 5B. FIG. 5A is a third type schematic cross-sectional view taken along line A-A of FIG. 1B, and FIG. 5B is a third type schematic cross-sectional view of the display panel provided in one embodiment of the present application. The difference between FIGS. 5A and 5B compared to FIGS. 4A and 4B is that the display panel 200 additionally includes a second inorganic layer 203 and a third organic filler layer 113. The second inorganic layer 203 is positioned on one side of the encapsulation layer 23 that is away from the substrate 204, and the third organic filler layer 113 is disposed between the second inorganic layer 203 and the encapsulation layer 23, and is located on one side of the barrier structure 114 away from the display area 1a.

In this scenario, the stacked structure 10 consists of sequentially layered components: the first inorganic layer 201, the first organic filler layer 111, the first inorganic encapsulation layer 231, the second organic filler layer 112, the second inorganic encapsulation layer 232, the third organic filler layer 113, and the second inorganic layer 203.

It is understandable that in the peripheral area 1b, if the second inorganic encapsulation layer 232 and the second inorganic layer 203 were in direct contact, these two layers would be equivalent to a single, thicker inorganic film layer. This would increase the risk of cracks forming during the cutting process. This application mitigates this risk by incorporating the third organic filler layer 113, which ensures that the second inorganic encapsulation layer 232 and the second inorganic layer 203 are spaced apart, preventing direct contact. This is analogous to splitting the thick inorganic film layer formed by the stacking of the second inorganic encapsulation layer 232 and the second inorganic layer 203. Consequently, the stacked structure 10 forms an inorganic/organic/inorganic/organic/inorganic/organic/inorganic layered structure, reducing the risk of cracks during cutting.

Similarly, the third organic filler layer 113 is an organic film layer that acts as a stress buffer, further reducing the risk of cracks forming during the cutting process.

Please refer again to FIG. 3. The display panel 200 also includes a touch layer 24. The touch layer 24 is positioned on one side of the encapsulation layer 23 that is away from the substrate 204. The touch layer 24 includes a first insulation layer 241, touch electrodes 242, and a second insulation layer 243. The first insulation layer 241 extends from the display area 1a and covers the peripheral area 1b. The touch electrodes 242 are located on one side of the first insulation layer 241 that is away from the substrate 204 and situated in the display area 1a. The second insulation layer 243 covers one side of the touch electrodes 242 that is away from the substrate 204.

The material for the first insulation layer 241 is an inorganic material, and in this embodiment, the second inorganic layer 203 can include the first insulation layer 241.

In the present embodiment, the third organic filler layer 113 can include the same organic material as the organic encapsulation layer 233.

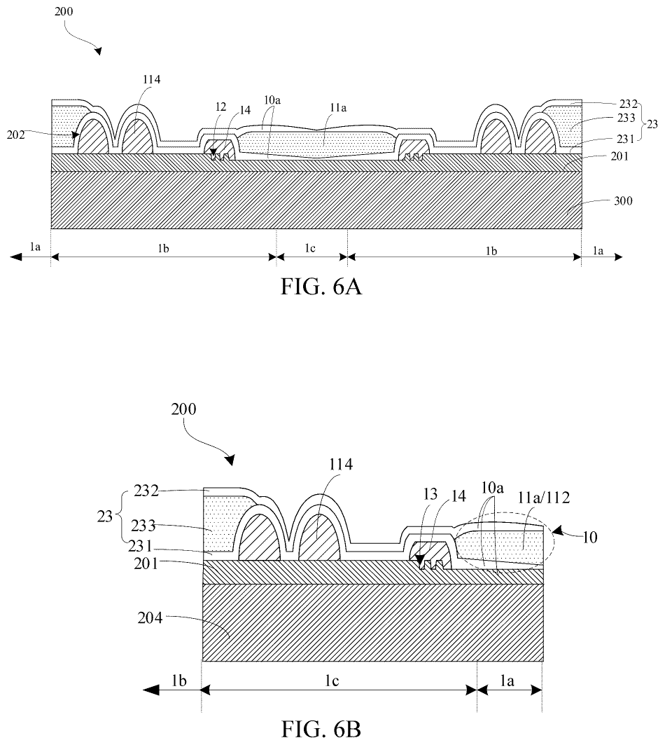

In one embodiment, please refer to FIGS. 6A and 6B. FIG. 6A is a fourth type schematic cross-sectional view taken along line A-A of FIG. 1B, and FIG. 6B is a fourth type schematic cross-sectional view of the display panel provided in one embodiment of the present application. The difference between FIGS. 6A and 6B and FIGS. 2A and 2B is that the second organic filler layer 112 is positioned between the first inorganic encapsulation layer 231 and the second inorganic encapsulation layer 232. In this case, the stacked structure 10 includes sequentially layered components: the first inorganic encapsulation layer 231, the second organic filler layer 112, and the second inorganic encapsulation layer 232.

It is understandable that the second organic filler layer 112 is positioned between the first inorganic encapsulation layer 201 and the first inorganic encapsulation layer 231. This is analogous to splitting the thicker inorganic film layer formed by the stacking of the first inorganic encapsulation layer 231 and the second inorganic encapsulation layer 232, resulting in an inorganic/organic/inorganic layered structure within the stacked structure 10. This configuration mitigates the risk of cracks during the cutting process.

In this embodiment, the second organic filler layer 112 can be composed of the same organic material as the organic encapsulation layer 233.

Furthermore, in this embodiment, the first inorganic layer 201 also includes at least one groove 12 on one side of the barrier structure 114 away from the display area la. The first organic layer 202 includes a crack prevention layer 14 positioned between the barrier structure 114 and the stacked structure 10. The crack prevention layer 14 covers the groove 12.

In this embodiment, the first inorganic encapsulation layer 231 covers the crack prevention layer 14, and the crack prevention layer 14 and the second organic filler layer 112 are separated by the first inorganic encapsulation layer 231.

Beneficial effects: The display panel provided in this embodiment includes a first inorganic layer, a first organic layer, and an encapsulation layer. The first organic layer includes a planarization layer in the display area and a barrier structure in the peripheral area. A stacked structure is formed in the peripheral area, located on one side of the barrier structure away from the display area. The stacked structure includes an inorganic sub-layer, an organic sub-layer, and an inorganic sub-layer, sequentially layered. A gap is formed between the organic sub-layer and the barrier structure, allowing the encapsulation layer to contact the first inorganic layer at the gap, thereby forming a complete encapsulation. Within the stacked structure, the organic sub-layer is positioned between two adjacent inorganic sub-layers, creating an inorganic/organic/inorganic alternately-layered structure. This is analogous to dividing a thick inorganic film layer into multiple thinner inorganic sub-layers. This configuration significantly reduces the risk of cracks forming in the stacked structure during the cutting of the display mother panel. This approach enables the realization of ultra-narrow bezels while simultaneously enhancing the performance and longevity of the light-emitting devices in the display panel.

In summary, although the present application has been disclosed in the preferred embodiments as described above, the preferred embodiments are not intended to limit the application. Those skilled in the art can make various modifications and refinements without departing from the spirit and scope of this application. Therefore, the scope of protection of this application is defined by the scope of the claims.

1. A display panel comprising a display area and at least one peripheral area located on at least one side of the display area, the display panel comprising:
a substrate;
a first inorganic layer disposed on one side of the substrate;
a first organic layer disposed on one side of the first inorganic layer away from the substrate, wherein the first organic layer comprises a planarization layer disposed in the display area and a barrier structure disposed in the peripheral area; and
an encapsulation layer disposed on one side of the first organic layer away from the substrate;
wherein the display panel further comprises a stacked structure disposed in the peripheral area and located on one side of the barrier structure away from the display area, the stacked structure comprising an inorganic sub-layer, an organic sub-layer, and an inorganic sub-layer, sequentially layered, wherein a gap is defined between the organic sub-layer and the barrier structure, and the encapsulation layer contacts the first inorganic layer at the gap.

2. The display panel according to claim 1, wherein the encapsulation layer comprises a first inorganic encapsulation layer, a first organic encapsulation layer, and a second inorganic encapsulation layer, sequentially layered;
wherein the first inorganic encapsulation layer covers the display area and extends to cover the barrier structure, and the first inorganic encapsulation layer contacts the first inorganic layer at the gap.

3. The display panel according to claim 2, wherein the first organic layer further comprises a first organic filler layer disposed on one side of the barrier structure away from the display area;
wherein the stacked structure comprises the first inorganic layer, the first organic filler layer, and the first inorganic encapsulation layer, sequentially layered.

4. The display panel according to claim 3, wherein the first inorganic layer comprises at least one groove defined on one side of the barrier structure away from the display area;
wherein the first organic filler layer covers the groove.

5. The display panel according to claim 3, wherein the first organic layer further comprises:
a pixel definition layer disposed on one side of the planarization layer away from the substrate; and
a plurality of support pillars disposed on one side of the pixel definition layer away from the substrate;
wherein the first organic filler layer comprises a same organic material as one or a combination of the planarization layer, the pixel definition layer, and the support pillars.

6. The display panel according to claim 3, wherein the stacked structure comprises the first inorganic layer, the first organic filler layer, the first inorganic encapsulation layer, a second organic filler layer, and the second inorganic encapsulation layer, sequentially layered;
wherein the second organic filler layer comprises a same organic material as the organic encapsulation layer.

7. The display panel according to claim 6, further comprising:
a second inorganic layer disposed on one side of the encapsulation layer away from the substrate; and
a third organic filler layer, disposed between the second inorganic layer and the encapsulation layer and located on one side of the barrier structure away from the display area;
wherein the stacked structure comprises the first inorganic layer, the first organic filler layer, the first inorganic encapsulation layer, the second organic filler layer, the second inorganic encapsulation layer, the third organic filler layer, and the second inorganic layer, sequentially layered, and wherein the third organic filler layer comprises a same organic material as the organic encapsulation layer.

8. The display panel according to claim 2, wherein the stacked structure comprises the first inorganic encapsulation layer, a second organic filler layer, and the second inorganic encapsulation layer, sequentially layered;
wherein the second organic filler layer comprises a same organic material as the organic encapsulation layer.

9. The display panel according to claim 8, wherein the first inorganic layer further comprises at least one groove defined on one side of the barrier structure away from the display area, and the first organic layer further comprises a crack prevention layer disposed between the barrier structure and the stacked structure, the crack prevention layer covering the groove.

10. The display panel according to claim 1, wherein a thickness of the organic sub-layer is in a range of 2 micrometers to 10 micrometers.

11. A display panel comprising a display area and at least one peripheral area located on at least one side of the display area, the display panel comprising:
a substrate;
a first inorganic layer disposed on one side of the substrate;
a first organic layer disposed on one side of the first inorganic layer away from the substrate, wherein the first organic layer comprises a planarization layer disposed in the display area and a barrier structure disposed in the peripheral area;
an encapsulation layer disposed on one side of the first organic layer away from the substrate; and
a driving circuit layer, disposed on one side of the substrate, comprising a plurality of inorganic film layers and a plurality of organic film layers, wherein the first inorganic layer comprises one or more inorganic film layers combined within the driving circuit layer, and the first organic layer comprises one or more organic film layers combined within the driving circuit layer;
wherein the display panel further comprises a stacked structure disposed in the peripheral area and located on one side of the barrier structure away from the display area, the stacked structure comprising an inorganic sub-layer, an organic sub-layer, and an inorganic sub-layer, sequentially layered, wherein a gap is defined between the organic sub-layer and the barrier structure, and the encapsulation layer contacts the first inorganic layer at the gap.

12. The display panel according to claim 11, wherein the encapsulation layer comprises a first inorganic encapsulation layer, a first organic encapsulation layer, and a second inorganic encapsulation layer, sequentially layered;
wherein the first inorganic encapsulation layer covers the display area and extends to cover the barrier structure, and the first inorganic encapsulation layer contacts the first inorganic layer at the gap.

13. The display panel according to claim 12, wherein the first organic layer further comprises a first organic filler layer disposed on one side of the barrier structure away from the display area;
wherein the stacked structure comprises the first inorganic layer, the first organic filler layer, and the first inorganic encapsulation layer, sequentially layered.

14. The display panel according to claim 13, wherein the first inorganic layer comprises at least one groove defined on one side of the barrier structure away from the display area;
wherein the first organic filler layer covers the groove.

15. The display panel according to claim 13, wherein the first organic layer further comprises:
a pixel definition layer disposed on one side of the planarization layer away from the substrate; and
a plurality of support pillars disposed on one side of the pixel definition layer away from the substrate;
wherein the first organic filler layer comprises a same organic material as one or a combination of the planarization layer, the pixel definition layer, and the support pillars.

16. The display panel according to claim 13, wherein the stacked structure comprises the first inorganic layer, the first organic filler layer, the first inorganic encapsulation layer, a second organic filler layer, and the second inorganic encapsulation layer, sequentially layered;
wherein the second organic filler layer comprises a same organic material as the organic encapsulation layer.

17. The display panel according to claim 16, further comprising:
a second inorganic layer disposed on one side of the encapsulation layer away from the substrate; and
a third organic filler layer, disposed between the second inorganic layer and the encapsulation layer and located on one side of the barrier structure away from the display area;
wherein the stacked structure comprises the first inorganic layer, the first organic filler layer, the first inorganic encapsulation layer, the second organic filler layer, the second inorganic encapsulation layer, the third organic filler layer, and the second inorganic layer, sequentially layered, and wherein the third organic filler layer comprises a same organic material as the organic encapsulation layer.

18. The display panel according to claim 12, wherein the stacked structure comprises the first inorganic encapsulation layer, the second organic filler layer, and the second inorganic encapsulation layer, sequentially layered;
wherein the second organic filler layer comprises a same organic material as the organic encapsulation layer.

19. The display panel according to claim 18, wherein the first inorganic layer further comprises at least one groove defined on one side of the barrier structure away from the display area, and the first organic layer further comprises a crack prevention layer disposed between the barrier structure and the stacked structure, the crack prevention layer covering the groove.

20. The display panel according to claim 11, wherein a thickness of the organic sub-layer is in a range of 2 micrometers to 10 micrometers.
